(19) United States
(12) Patent Application Publication
(10) Pub. No.: US 2024/0022231 A1
(43) Pub. Date: Jan. 18, 2024

(54) ACOUSTIC WAVE DEVICE

(71) Applicant: Murata Manufacturing Co., Ltd., Nagaokakyo-shi (JP)

(72) Inventors: Kazunori INOUE, Nagaokakyo-shi (JP); Tetsuya KIMURA, Nagaokakyo-shi (JP); Katsumi SUZUKI, Nagaokakyo-shi (JP); Yuta ISHII, Nagaokakyo-shi (JP)

(21) Appl. No.: 18/374,113

(22) Filed: Sep. 28, 2023

Related U.S. Application Data
(63) Continuation of application No. PCT/JP2022/015377, filed on Mar. 29, 2022.
(60) Provisional application No. 63/168,310, filed on Mar. 31, 2021.
(60) Provisional application No. 63/168,326, filed on Mar. 31, 2021.

(51) Int. Cl. H03H 9/17; H03H 9/02

(52) U.S. Cl. CPC H03H 9/173; H03H 9/02015; H03H 9/02086

(57) ABSTRACT

An acoustic wave device includes a piezoelectric layer including a first major surface and a second major surface facing each other, a functional electrode on at least one of the first major surface and the second major surface of the piezoelectric layer, and a support substrate laminated on the second major surface side of the piezoelectric layer. An air gap is provided between the support substrate and the piezoelectric layer. At least a portion of the functional electrode overlaps the air gap as seen in a lamination direction of the support substrate and the piezoelectric layer. A through-hole penetrates the piezoelectric layer and reaches the air gap. A protrusion is provided in a region of an outer edge of the through-hole in the first major surface of the piezoelectric layer and is more protruded than a region where the through-hole is not provided.

### CROSS REFERENCE TO RELATED APPLICATIONS

This application claims the benefit of priority to Provisional Application Nos. 63/168,310 and 63/168,326 filed on Mar. 31, 2021, and is a Continuation Application of PCT Application No. PCT/JP2022/015377 filed on Mar. 29, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices including a piezoelectric layer including lithium niobate or lithium tantalate have been known.

Japanese Unexamined Patent Application Publication No. 2012-257019 discloses an acoustic wave device including a support with an air gap formed therein, a piezoelectric substrate provided on the support so as to overlap the air gap, and an interdigital transducer (IDT) electrode provided on the piezoelectric substrate so as to overlap the air gap. The IDT electrode excites plate waves. The edge of the air gap does not include any straight portion extending in parallel to the propagation direction of plate waves excited by the IDT electrode.

### SUMMARY OF THE INVENTION

When a through-hole that penetrates the piezoelectric layer and reaches the air gap is provided in the piezoelectric layer in an acoustic wave device as described in Japanese Unexamined Patent Application Publication No. 2012-257019, cracks starting from the through-hole can occur in the piezoelectric layer.

Preferred embodiments of the present invention provide acoustic wave devices in each of which, cracks, starting from a through-hole penetrating the piezoelectric layer, are reduced or prevented.

An acoustic wave device according to a preferred embodiment of the present invention includes a piezoelectric layer including a first major surface and a second major surface that face each other, a functional electrode provided on at least one of the first major surface and the second major surface of the piezoelectric layer, and a support substrate laminated on the second major surface side of the piezoelectric layer. An air gap is provided between the support substrate and the piezoelectric layer. At least a portion of the functional electrode overlaps the air gap as seen in a lamination direction of the support substrate and the piezoelectric layer. A through-hole that penetrates the piezoelectric layer and reaches the air gap is provided. A protrusion is provided in a region defining an outer edge of the through-hole in the first major surface of the piezoelectric layer and is more protruded than a region where the through-hole is not provided.

According to preferred embodiments of the present invention, it is possible to provide acoustic wave devices in each of which, cracks starting from a through-hole penetrating a piezoelectric layer, are reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic cross-sectional view of an example of an acoustic wave device according to Example 1.

FIG. 2 is a schematic top view of the example of the acoustic wave device according to Example 1.

FIG. 3 is an enlarged top view of an example of a part around a through-hole in FIG. 2.

FIG. 4 is a cross-sectional view along a line A-A in FIG. 3.

FIG. 5 is a schematic cross-sectional view of a shape example of a protrusion whose outer wall is widened from inside toward outside.

FIG. 6 is a schematic cross-sectional view of a shape example of a protrusion whose outer wall is narrowed from inside toward outside.

FIG. 7 is a schematic cross-sectional view of a shape example of a protrusion whose outer wall includes a curved surface.

FIG. 8 is a schematic cross-sectional view of a shape example of a protrusion whose inner wall includes a curved surface.

FIG. 9 is an enlarged top view of another example of the portion around the through-hole in FIG. 2.

FIG. 10 is a cross-sectional view along a line A-A in FIG. 9.

FIG. 11 is a schematic cross-sectional view of an example of a process to form a sacrificial layer on a piezoelectric substrate.

FIG. 12 is a schematic cross-sectional view of an example of a process to form a joint layer.

FIG. 13 is a schematic cross-sectional view of an example of a process to bond a support substrate to the joint layer.

FIG. 14 is a schematic cross-sectional view of an example of a process to thin the piezoelectric substrate.

FIG. 15 is a schematic cross-sectional view of an example of a process to form functional electrodes and wiring electrodes.

FIG. 16 is a schematic cross-sectional view of an example of a process to form the through-hole.

FIG. 17 is a schematic cross-sectional view of an example of a process to remove the sacrificial layer.

FIG. 18 is a schematic cross-sectional view of an example of an acoustic wave device according to Example 2.

FIG. 19 is a schematic top view of the example of the acoustic wave device according to Example 2.

FIG. 20 is an enlarged cross-sectional view of an example of a portion indicated by Q in FIG. 18.

FIG. 21 is a schematic cross-sectional view of an example of a reinforcement film provided on a first major surface of a piezoelectric layer and a sidewall of the through-hole.

FIG. 22 is a schematic cross-sectional view of an example of a reinforcement film provided on the first major surface of the piezoelectric layer, the sidewall of the through-hole, and a second major surface of the piezoelectric layer.

FIG. 23 is a schematic cross-sectional view of another example of a reinforcement film provided on the first major surface of the piezoelectric layer, the sidewall of the through-hole, and the second major surface of the piezoelectric layer.

FIG. 24 is a schematic cross-sectional view of still another example of a reinforcement film provided on the first major surface of the piezoelectric layer, the sidewall of the through-hole, and the second major surface of the piezoelectric layer.

FIG. 25 is a schematic top view of an example of a reinforcement film provided on the sidewall of the through-hole so as to surround the through-hole.

FIG. 26 is a schematic cross-sectional view of an example of a reinforcement film provided on the sidewall of the through-hole so as to surround the through-hole.

FIG. 27 is a schematic top view of an example of a reinforcement film provided only on a portion of the sidewall of the through-hole on the air gap side.

FIG. 28 is a schematic cross-sectional view of an example of a reinforcement film provided only on a portion of the sidewall of the through-hole on the air gap side.

FIG. 29 is a schematic top view of an example of reinforcement films each provided on the second major surface of the piezoelectric layer so as to surround the through-hole.

FIG. 30 is a schematic cross-sectional view of an example of a reinforcement film provided on the second major surface of the piezoelectric layer so as to surround the through-hole.

FIG. 31 is a schematic top view of a shape example of a reinforcement film provided on the second major surface of the piezoelectric layer near a right through-hole.

FIG. 32 is a schematic top view of another shape example of the reinforcement film provided on the second major surface of the piezoelectric layer near the right through-hole.

FIG. 33 is a schematic top view of still another shape example of the reinforcement film provided on the second major surface of the piezoelectric layer near the right through-hole.

FIG. 34 is a schematic top view of an example of a reinforcement film that is provided near the right through-hole and includes a dielectric.

FIG. 35 is a schematic top view of another example of a reinforcement film that is provided near the right through-hole and includes a dielectric.

FIG. 36 is a schematic top view of still another example of a reinforcement film that is provided near the right through-hole and includes a dielectric.

FIG. 37 is a schematic top view of an example of a reinforcement film that is provided near the right through-hole and includes a reinforcement film including a dielectric and a reinforcement film including a metal.

FIG. 38 is a schematic cross-sectional view of an example of a process to form a reinforcement layer on a piezoelectric substrate.

FIG. 39 is a schematic cross-sectional view of an example of a process to form a sacrificial layer on the piezoelectric substrate.

FIG. 40 is a schematic cross-sectional view of an example of a process to form a joint layer.

FIG. 41 is a schematic cross-sectional view of an example of a process to bond a support substrate to the joint layer.

FIG. 42 is a schematic cross-sectional view of an example of a process to thin the piezoelectric substrate.

FIG. 43 is a schematic cross-sectional view of an example of a process to form functional electrodes and wiring electrodes.

FIG. 44 is a schematic cross-sectional view of an example of a process to form through-holes.

FIG. 45 is a schematic cross-sectional view of an example of a process to remove the sacrificial layer.

FIG. 46 is a schematic top view of an example of an acoustic wave device according to Example 3.

FIG. 47 is a schematic top view of another example of the acoustic wave device according to Example 3.

FIG. 48 is a schematic perspective view of the exterior of an example of an acoustic wave device using thickness-shear mode bulk waves.

FIG. 49 is a plan view of an electrode structure on the piezoelectric layer of the acoustic wave device illustrated in FIG. 48.

FIG. 50 is a cross-sectional view of a part along a line A-A in FIG. 48.

FIG. 51 is a schematic elevational cross-sectional view for explaining Lamb waves propagating in a piezoelectric film of an acoustic wave device.

FIG. 52 is a schematic elevational cross-sectional view for explaining thickness-shear mode bulk waves propagating in the piezoelectric layer of an acoustic wave device.

FIG. 53 is a diagram illustrating the amplitude direction of thickness-shear mode bulk waves.

FIG. 54 is a diagram illustrating an example of resonance characteristics of the acoustic wave device illustrated in FIG. 48.

FIG. 55 is a diagram illustrating the relationship between d/2p and the fractional bandwidth as a resonator of an acoustic wave device where p is the center-to-center distance between adjacent electrodes and d is the thickness of the piezoelectric layer.

FIG. 56 is a plan view of another example of the acoustic wave device using thickness-shear mode bulk waves.

FIG. 57 is a referential diagram illustrating an example of resonance characteristics of the acoustic wave device illustrated in FIG. 48.

FIG. 58 is a diagram illustrating the relationship in many acoustic wave resonators formed according to the third preferred embodiment of the present invention, between the fractional bandwidth and the amount of phase rotation, which is regarded as the magnitude of spurious and is normalized by 180 degrees, of the impedance of the spurious.

FIG. 59 is a diagram illustrating the relationship between d/2p, metallization ratio MR, and fractional bandwidth.

FIG. 60 is a diagram illustrating a fractional bandwidth map with respect to Euler angles (0°, θ, ψ) of LiNbO₃ when d/p is reduced infinitesimally close to zero.

FIG. 61 is a partially-cutaway perspective view for explaining an example of an acoustic wave device using Lamb waves.

FIG. 62 is a schematic cross-sectional view of an example of an acoustic wave device using bulk waves.

### DETAILED DESCRIPTION OF THE PREFERRED EMBODIMENTS

Hereinafter, acoustic wave devices according to preferred embodiments of the present invention will be described.

In first, second, and third aspects of a preferred embodiment of the present invention, an acoustic wave device includes a piezoelectric layer including lithium niobate or lithium tantalate, and a first electrode and a second electrode that face each other in a direction that intersects the thickness direction of the piezoelectric layer.

The first aspect uses bulk waves in the thickness-shear mode, such as a first thickness-shear mode. In the second aspect, the first electrode and the second electrode are electrodes adjacent to each other, and d/p is not greater than about 0.5, for example, where d is the thickness of the piezoelectric layer and p is the center-to-center distance between the first and second electrodes. In the first and second aspects, therefore, the Q value can be increased even when a size is reduced.

The third aspect uses Lamb waves as plate waves. Resonance characteristics by the Lamb waves can be obtained.

In a fourth aspect, an acoustic wave device according to a preferred embodiment of the present invention includes a piezoelectric layer including lithium niobate or lithium tantalate, and an upper electrode and a lower electrode that face each other in the thickness direction of the piezoelectric layer with the piezoelectric layer interposed therebetween. The fourth aspect uses bulk waves.

Hereinafter, the present invention is clarified by describing specific preferred embodiments of the present invention with reference to the drawings.

The drawings illustrated below are schematic, and the dimensions, aspect ratio scales, and the like in the drawings are sometimes different from those of actual products.

The preferred embodiments described in the specification are illustrative. Some components of each preferred embodiment can be partially substituted for or combined with corresponding components of another preferred embodiment. Each preferred embodiment is referred to as just an “acoustic wave device according to a preferred embodiment of the present invention” when not distinguished from the other preferred embodiments.

### First Preferred Embodiment

An acoustic wave device according to a first preferred embodiment of the present invention includes a through-hole that penetrates the piezoelectric layer and reaches an air gap. A protrusion is provided in a region defining an outer edge of the through-hole in a first major surface (that is, the major surface opposite to the air gap) of the piezoelectric layer. The protrusion is more protruded than the region where the through-hole is not provided. In other words, the portion of the piezoelectric layer that defines the outer edge of the through-hole is more protruded than another portion of the piezoelectric layer in the region where the through-hole is not provided. By providing the protrusion in the portion of the piezoelectric layer that defines the outer edge of the through-hole, the outer edge of the through-hole is reinforced. This can reduce or prevent formation of cracks starting from the through-hole.

The acoustic wave device according to the first preferred embodiment of the present invention may be provided with a reinforcement film described in a second preferred embodiment of the present invention.

The following description illustrates examples as more specific disclosures of the acoustic wave device according to the first preferred embodiment of the present invention. The first preferred embodiment of the present invention is not necessarily limited to those examples.

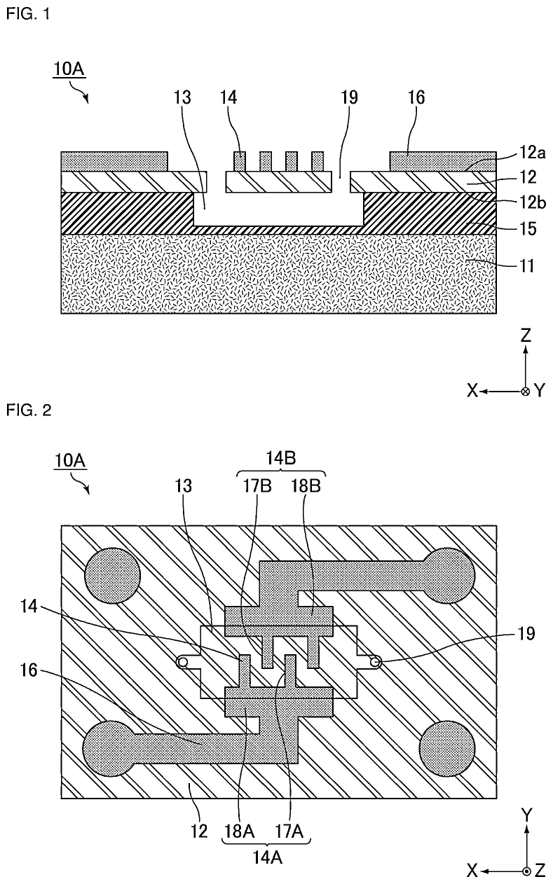

FIG. 1 is a schematic cross-sectional view of an example of an acoustic wave device according to Example 1. FIG. 2 is a schematic top view of the example of the acoustic wave device according to Example 1.

An acoustic wave device 10A according to Example 1, which is illustrated in FIGS. 1 and 2, includes a support substrate 11, an intermediate layer 15, which is laminated on the support substrate 11, and a piezoelectric layer 12, which is laminated on the intermediate layer 15. The piezoelectric layer 12 includes a first major surface 12a and a second major surface 12b, which face each other. On the piezoelectric layer 12, plural electrodes (functional electrodes 14 and other electrodes) are provided.

In the intermediate layer 15, an air gap 13 opened on the piezoelectric layer 12 side is provided. The air gap 13 may be provided in a portion of the intermediate layer 15 or may penetrate the intermediate layer 15. The air gap 13 may be provided for the support substrate 11. In this case, the air gap 13 may be provided in a portion of the support substrate 11 or may penetrate the support substrate 11. The intermediate layer 15 does not need to be provided. This means that the air gap 13 needs to be provided between the support substrate 11 and the piezoelectric layer 12.

The support substrate 11 includes silicon (Si), for example. The material of the support substrate 11 is not limited to the aforementioned material. Examples of the material of the support substrate 11 can include piezoelectrics, such as aluminum oxide, lithium tantalate, lithium niobate, and crystal, various types of ceramics, such as alumina, sapphire, silicon nitride, aluminum nitride, silicon carbide, zirconia, cordierite, mullite, steatite, and forsterite, dielectrics, such as diamond and glass, semiconductors, such as gallium nitride, and resin.

The intermediate layer 15 includes silicon oxide (SiOₓ), for example. In this case, the intermediate layer 15 may include SiO₂. The material of the intermediate layer 15 is not limited to the aforementioned material and can be silicon nitride (SiₓN_{y}) or the like, for example. In this case, the intermediate layer 15 may include Si₃N₄.

The piezoelectric layer 12 includes lithium niobate (LiNbOₓ) or lithium tantalate (LiTaOₓ), for example. In this case, the piezoelectric layer 12 may include LiNbO₃ or LiTaO₃.

The plural electrodes include at least a pair of the functional electrodes 14 and plural wiring electrodes 16, which are coupled to the respective functional electrodes 14. In the example illustrated in FIGS. 1 and 2, the functional electrodes 14 are provided on the first major surface 12a of the piezoelectric layer 12.

At least a portion of each functional electrode 14 is provided so as to overlap the air gap 13 as seen from the lamination direction of the support substrate 11 and the piezoelectric layer 12 (in a Z direction in FIGS. 1 and 2).

As illustrated in FIG. 2, the functional electrodes 14 include first electrodes 17A (hereinafter, also referred to as first electrode fingers 17A) and second electrodes 17B (hereinafter, also referred to as second electrode fingers 17B), which face each other, a first busbar electrode 18A, which is coupled to the first electrodes 17A, and a second busbar electrode 18B, which is coupled to the second electrodes 17B, for example. The first electrodes 17A and the first busbar electrode 18A define a first comb-shaped electrode (a first IDT electrode) as a first functional electrode 14A. The second electrodes 17B and the second busbar electrode 18B define a second comb-shaped electrode (a second IDT electrode) as a second functional electrode 14B.

The functional electrodes 14 include a proper metal or alloy, such as Al or AlCu alloy. For example, each functional electrode 14 includes a structure in which an Al layer is laminated on a Ti layer. The functional electrodes 14 may include an adhesion layer other than the Ti layer.

The wiring electrodes 16 include a proper metal or alloy, such as Al or AlCu alloy. For example, each wiring electrode 16 includes a structure in which an Al layer is laminated on a Ti layer. The wiring electrodes 16 may include an adhesion layer other than the Ti layer.

The piezoelectric layer 12 is provided with through-holes 19, which penetrate the piezoelectric layer 12 and reach the air gap 13. In the example illustrated in FIGS. 1 and 2, the through-holes 19 are provided outside the functional electrodes 14 in an X direction. The positions of the through-holes 19 are not limited, but the through-holes 19 penetrate the piezoelectric layer 12 in such positions as to not overlap the functional electrodes 14 as seen in the lamination direction of the support substrate 11 and the piezoelectric layer 12. The through-holes 19 are used as etching holes in a later-described production process, for example.

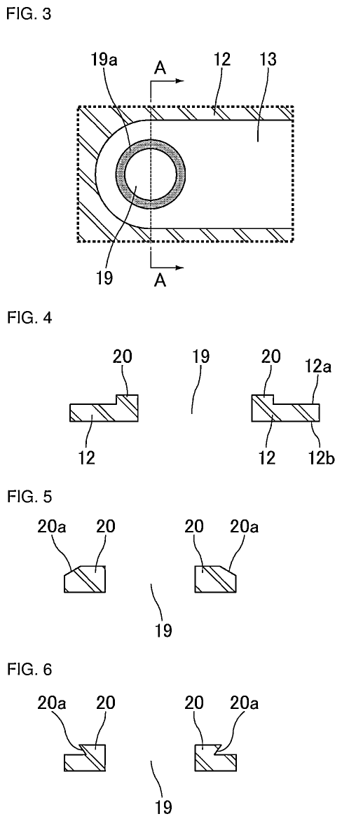

FIG. 3 is an enlarged top view of an example of a part around the through-hole in FIG. 2. FIG. 4 is a cross-sectional view along a line A-A in FIG. 3.

As illustrated in FIGS. 3 and 4, in the first major surface 12a of the piezoelectric layer 12, a protrusion 20 is provided in a region defining an outer edge 19a (see FIG. 3) of the through-hole 19 and is more protruded than the region where any through-hole 19 is not provided. By providing the protrusion in the piezoelectric layer 12, the through-hole 19 is improved in strength. This can reduce or prevent formation of cracks starting from the through-hole 19.

The shape of the through-hole 19 as seen in the lamination direction of the support substrate 11 and the piezoelectric layer 12 is not limited, but, preferably, at least a portion of the through-hole 19 is curved, like a circular or elliptical shape. When at least a portion of the through-hole 19 is curved as seen in the lamination direction of the support substrate 11 and the piezoelectric layer 12, stress concentration to the outer edge 19a of the through-hole 19 is less likely to occur. This can further reduce or prevent formation of cracks in the piezoelectric layer 12.

The following description illustrates modifications of the first preferred embodiment of the present invention.

FIG. 5 is a schematic cross-sectional view of a shape example of a protrusion whose outer wall is widened from inside toward outside. FIG. 6 is a schematic cross-sectional view of a shape example of a protrusion whose outer wall is narrowed from inside toward outside.

The protrusion 20 may be tapered such that an outer wall of the protrusion 20 is widened from inside toward outside as illustrated in FIG. 5 or such that the outer wall 20a of the protrusion 20 is narrowed from inside toward outside as illustrated in FIG. 6. When the outer wall 20a of the protrusion 20 has a shape widened from inside toward outside or a shape narrowed from inside toward outside, stress concentration to the outer edge 19a (see FIG. 3) of the through-hole 19 is less likely to occur. This can further reduce or prevent formation of cracks in the piezoelectric layer 12.

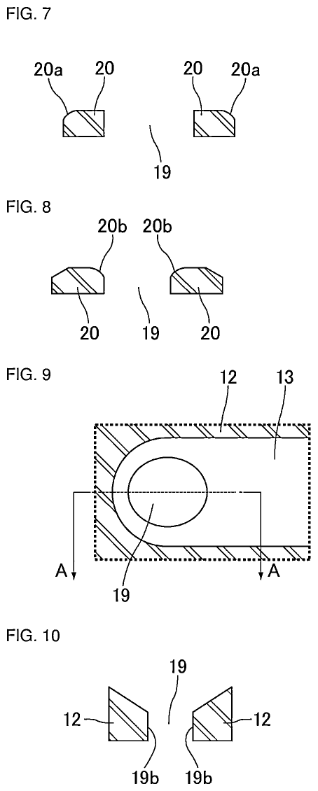

FIG. 7 is a schematic cross-sectional view of a shape example of a protrusion whose outer wall includes a curved surface. FIG. 8 is a schematic cross-sectional view of a shape example of a protrusion whose inner wall shape includes a curved surface.

The outer wall 20a of the protrusion 20 may include a curved surface as illustrated in FIG. 7. An inner wall 20b of the protrusion 20 may include a curved surface as illustrated in FIG. 8. Furthermore, both the outer wall 20a and the inner wall 20b of the protrusion 20 may include a curved surface. When at least a portion of the protrusion 20 includes a curved surface as described above, stress concentration to the outer edge 19a (see FIG. 3) of the through-hole 19 is less likely to occur, thus reducing or preventing formation of cracks in the piezoelectric layer 12.

FIG. 9 is an enlarged top view of another example of the part around the through-hole in FIG. 2. FIG. 10 is a cross-sectional view along a line A-A in FIG. 9. FIGS. 9 and 10 do not illustrate the protrusion 20 of the piezoelectric layer 12.

As illustrated in FIG. 10, the end portion (the upper end portion in FIG. 10) of the through-hole 19 on the first major surface 12a side of the piezoelectric layer 12 may include an inverse tapered shape increasing in cross-sectional area (or diameter) toward the first major surface 12a of the piezoelectric layer 12. In this case, a sidewall 19b of the through-hole 19 and the piezoelectric layer 12 can define an obtuse angle. This can prevent cracks from easily forming due to stress concentration.

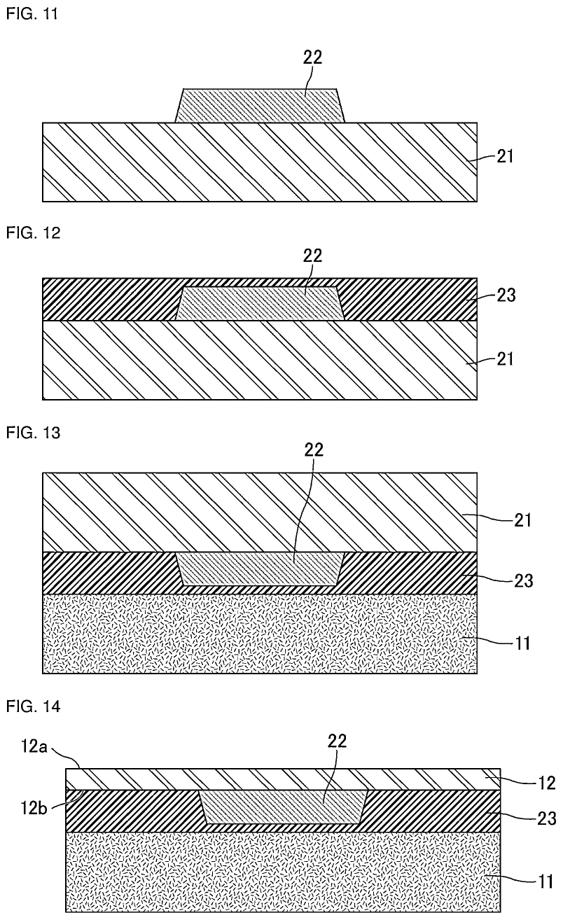

An example of a method of manufacturing the acoustic wave device according to the first preferred embodiment of the present invention will be described with reference to FIGS. 11 to 17.

FIG. 11 is a schematic cross-sectional view of an example of a process to form a sacrificial layer on a piezoelectric substrate.

As illustrated in FIG. 11, a sacrificial layer 22 is formed on a piezoelectric substrate 21.

The piezoelectric substrate 21 can be a substrate composed of LiNbO₃, LiTaO₃, or the like, for example.

The material of the sacrificial layer 22 can be a proper material that can be removed by etching described later. For example, the material of the sacrificial layer 22 is a dielectric film soluble in a mild acid, such as ZnO or MgO film, or a heat-resistant resin soluble in a solvent.

The sacrificial layer 22 can be formed by the following method, for example. First, a ZnO film is formed by sputtering, followed by resist coating, exposure, and development in this order. Then, wet-etching is performed to form a pattern of the sacrificial layer 22. The sacrificial layer 22 may be formed by another method.

FIG. 12 is a schematic cross-sectional view of an example of a process to form a joint layer.

As illustrated in FIG. 12, a joint layer 23 is formed so as to cover the sacrificial layer 22, and then the surface of the joint layer 23 is flattened.

The joint layer 23 is a SiO₂ film or the like, for example. The joint layer 23 can be formed by sputtering, for example. The flattening of the joint layer 23 can be performed by chemical mechanical polishing (CMP) or the like, for example.

FIG. 13 is a schematic cross-sectional view of an example of a process to bond a support substrate to the joint layer.

As illustrated in FIG. 13, the joint layer 23 is bonded to the support substrate 11.

FIG. 14 is a schematic cross-sectional view of an example of a process to thin the piezoelectric substrate.

As illustrated in FIG. 14, the piezoelectric substrate 21 is thinned. The piezoelectric layer 12 is thus formed. The thinning of the piezoelectric substrate 21 can be performed by smart cut, polishing, or the like, for example.

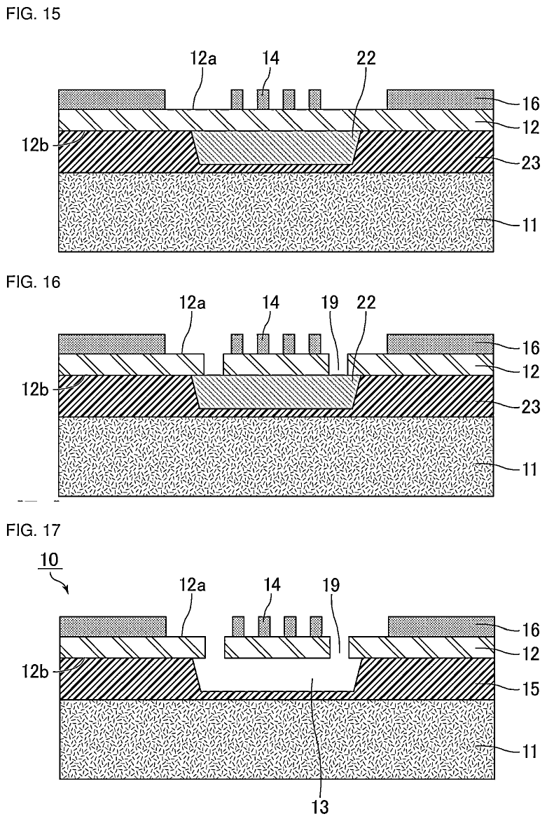

FIG. 15 is a schematic cross-sectional view of an example of a process to form functional electrodes and wiring electrodes.

As illustrated in FIG. 15, the functional electrodes 14 and the wiring electrodes 16 are formed on the first major surface 12a of the piezoelectric layer 12. The functional electrodes 14 and the wiring electrodes 16 can be formed by liftoff or the like, for example.

FIG. 16 is a schematic cross-sectional view of an example of a process to form through-holes.

As illustrated in FIG. 16, the through-holes 19 are formed in the piezoelectric layer 12. The through-holes 19 are formed so as to reach the sacrificial layer 22. The through-holes 19 can be formed by dry etching or the like, for example. The through-holes 19 are used as etching holes.

FIG. 17 is a schematic cross-sectional view of an example of a process to remove the sacrificial layer.

As illustrated in FIG. 17, the sacrificial layer 22 is removed by using the through-holes 19. When the material of the sacrificial layer 22 is ZnO, the sacrificial layer 22 can be removed by wet etching using a mixture solution of acetic acid, phosphoric acid, and water (acetic acid/phosphoric acid/water=1/1/10), for example.

The acoustic wave device 10 is obtained as described above. The protrusion 20 of the piezoelectric layer 12 illustrated in FIG. 4 and other drawings can be formed in the process to form the through-holes 19 by a method of making a hole with laser light, a method of forming the through-holes 19 by performing dry etching in two steps, or another method.

### Second Preferred Embodiment

In an acoustic wave device according to the second preferred embodiment of the present invention, the protrusion includes a reinforcement film provided on the first major surface (that is, the major surface opposite to the air gap) of the piezoelectric layer. By providing the reinforcement film in the aforementioned place as the protrusion, it is possible to reduce or prevent formation of cracks starting from the through-hole without interfering with excitation of the functional electrode.

The following description illustrates examples as more specific disclosures of the acoustic wave device according to the second preferred embodiment of the present invention. The second preferred embodiment of the present invention is not necessarily limited to those examples.

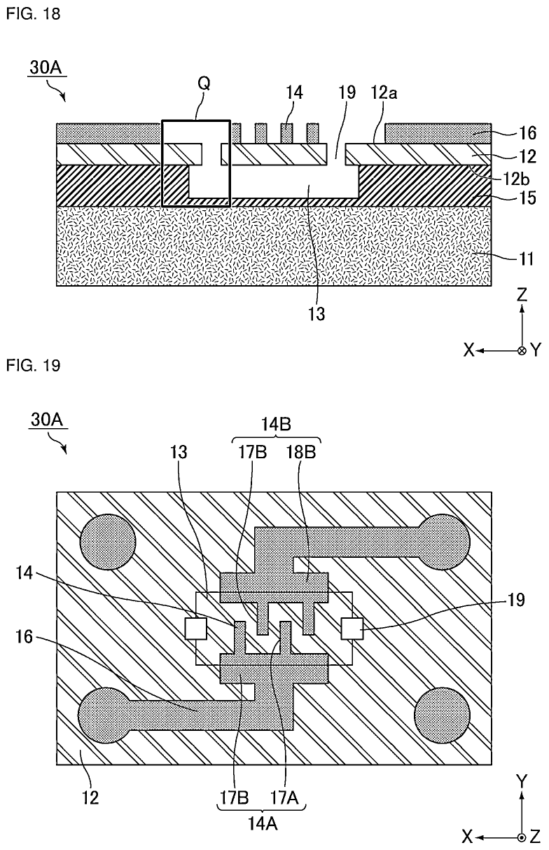

FIG. 18 is a schematic cross-sectional view of an example of an acoustic wave device according to Example 2. FIG. 19 is a schematic top view of the example of the acoustic wave device according to Example 2.

An acoustic wave device 30A according to Example 2, which is illustrated in FIGS. 18 and 19, includes the support substrate 11, the intermediate layer 15, which is laminated on the support substrate 11, and the piezoelectric layer 12, which is laminated on the intermediate layer 15. The piezoelectric layer 12 includes the first major surface 12a and the second major surface 12b, which face each other. On the piezoelectric layer 12, plural electrodes (the functional electrodes 14 and other electrodes) are provided.

In the intermediate layer 15, the air gap 13 opened on the piezoelectric layer 12 side is provided. The air gap 13 may be provided in a portion of the intermediate layer 15 or may penetrate the intermediate layer 15. The air gap 13 may be provided for the support substrate 11. In this case, the air gap 13 may be provided in a portion of the support substrate 11 or may penetrate the support substrate 11. The intermediate layer 15 does not need to be provided. This means that the air gap 13 needs to be provided between the support substrate 11 and the piezoelectric layer 12.

The plural electrodes include at least a pair of the functional electrodes 14 and plural wiring electrodes 16, which are coupled to the respective functional electrodes 14. In the example illustrated in FIGS. 18 and 19, the functional electrodes 14 are provided on the first major surface 12a of the piezoelectric layer 12.

As seen in the lamination direction of the support substrate 11 and the piezoelectric layer 12 (in the Z direction in FIGS. 18 and 19), at least a portion of each functional electrode 14 is provided so as to overlap the air gap 13.

As illustrated in FIG. 19, the functional electrodes 14 include the first electrodes 17A (hereinafter, also referred to as the first electrode fingers 17A) and the second electrodes 17B (hereinafter, also referred to as the second electrode fingers 17B), which face each other, the first busbar electrode 18A, which is coupled to the first electrodes 17A, and the second busbar electrode 18B, which is coupled to the second electrodes 17B, for example. The first electrodes 17A and the first busbar electrode 18A define a first comb-shaped electrode (the first IDT electrode) as the first functional electrode 14A. The second electrodes 17B and the second busbar electrode 18B define a second comb-shaped electrode (the second IDT electrode) as the second functional electrode 14B.

The piezoelectric layer 12 is provided with the through-holes 19, which penetrate the piezoelectric layer 12 and reach the air gap 13. In the example illustrated in FIGS. 18 and 19, the through-holes 19 are provided outside the functional electrodes 14 in the X direction. The positions of the through-holes 19 are not limited, but the through-holes 19 penetrate the piezoelectric layer 12 in such positions as to not overlap the functional electrodes 14 as seen in the lamination direction of the support substrate 11 and the piezoelectric layer 12. The through-holes 19 are used as etching holes in a later-described production process, for example.

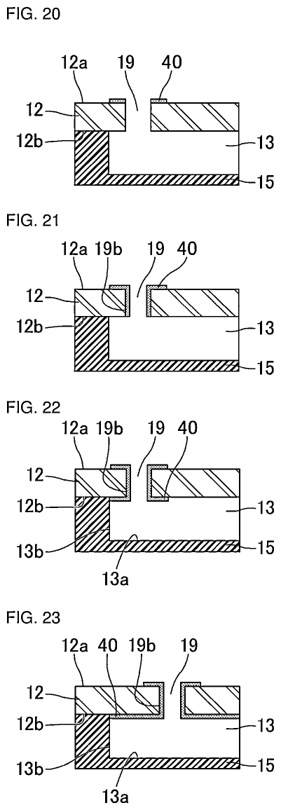

FIG. 20 is an enlarged cross-sectional view of an example of a portion indicated by Q in FIG. 18.

As illustrated in FIG. 20, a reinforcement film 40 is provided on the first major surface 12a of the piezoelectric layer 12. The reinforcement film 40 defines the protrusion 20 (see FIG. 4) of the piezoelectric layer 12. The first major surface 12a of the piezoelectric layer 12, which is fragile, can thereby be covered with the reinforcement film 40. This can reduce or prevent formation of cracks starting from the through-holes 19.

The material of the reinforcement film 40 is a dielectric, a metal, or the like, for example. The material of the reinforcement film 40 may be any one of SiO₂, SiN, and Al₂O₃.

The following description illustrates modifications of the second preferred embodiment of the present invention.

FIG. 21 is a schematic cross-sectional view of an example of a reinforcement film provided on the first major surface of the piezoelectric layer and the sidewall of the through-hole.

As illustrated in FIG. 21, another reinforcement film 40 may be provided on the sidewall 19b of the through-hole 19. By providing the reinforcement film 40 on the sidewall 19b of the through-hole 19, the sidewall 19b of the through-hole 19, which is fragile, can be covered with the reinforcement film 40. This can further reduce or prevent formation of cracks starting from the through-hole 19. When the reinforcement films 40 are provided on the first major surface 12a of the piezoelectric layer 12 and on the sidewall 19b of the through-hole 19, preferably, the reinforcement film 40 provided on the first major surface 12a of the piezoelectric layer 12 is contiguous to the reinforcement film provided on the sidewall 19b of the through-hole 19.

The reinforcement film 40 may be provided on the entire sidewall 19b of the through-hole 19 or may be provided only on a portion of the sidewall 19b of the through-hole 19.

When any reinforcement film 40 is provided on a portion of the sidewall 19b of the through-hole 19, preferably, the reinforcement film 40 is laid on the first major surface 12a of the piezoelectric layer 12 side or on the air gap 13 side in the sidewall 19b of the through-hole 19. Alternatively, the reinforcement film 40 and another reinforcement film 40 are separately provided on the respective sides. In this case, any reinforcement film 40 covers the piezoelectric layer 12 side or the air gap 13 side in the sidewall 19b of the through-hole 19, which are particularly subject to stress concentration. This can further facilitate reducing or preventing formation of cracks.

FIG. 22 is a schematic cross-sectional view of an example of a reinforcement film provided on the first major surface of the piezoelectric layer, the sidewall of the through-hole, and the second major surface of the piezoelectric layer. FIG. 23 is a schematic cross-sectional view of another example of a reinforcement film provided on the first major surface of the piezoelectric layer, the sidewall of the through-hole, and the second major surface of the piezoelectric layer.

As illustrated in FIG. 22 or 23, another reinforcement film 40 may be provided on the second major surface 12b of the piezoelectric layer 12. By providing the reinforcement film 40 on the second major surface 12b of the piezoelectric layer 12, the piezoelectric layer 12 can be supported on the second major surface 12b side. This can reduce deflection of the piezoelectric layer 12, thus reducing or preventing formation of cracks. When the reinforcement films 40 are provided on the first major surface 12a of the piezoelectric layer 12, the sidewall 19b of the through-hole 19, and the second major surface 12b of the piezoelectric layer 12, preferably, the reinforcement film 40 provided on the first major surface 12a of the piezoelectric layer 12 is contiguous to the reinforcement film 40 provided on the sidewall 19b of the through-hole 19, and the reinforcement film 40 provided on the sidewall 19b of the through-hole 19 is contiguous to the reinforcement film 40 provided on the second major surface 12b of the piezoelectric layer 12.

The reinforcement films 40 may be provided on the first major surface 12a of the piezoelectric layer 12 and the second major surface 12b of the piezoelectric layer 12 (not illustrated).

The reinforcement film 40 provided on the second major surface 12b of the piezoelectric layer 12 may be positioned so as to be contiguous to the through-hole 19 or may be positioned away from the through-hole 19.

The reinforcement film 40 provided on the second major surface 12b of the piezoelectric layer 12 is preferably spaced from the bottom surface 13a of the air gap 13. That is, the air gap 13 is preferably adjacent to the surface of the reinforcement film 40 provided on the second major surface 12b of the piezoelectric layer 12.

The reinforcement film 40 provided on the second major surface 12b of the piezoelectric layer 12 is preferably in contact with the sidewall 13b of the air gap 13 as illustrated in FIG. 22 or 23.

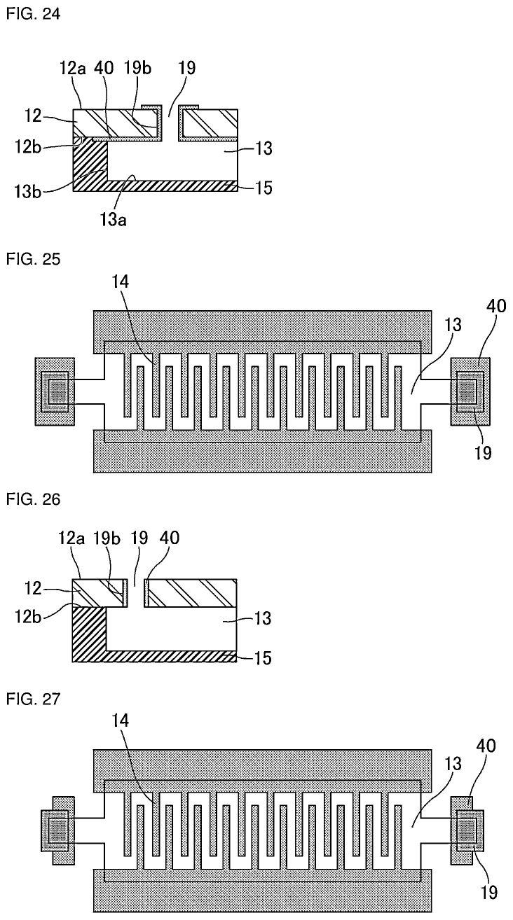

FIG. 24 is a schematic cross-sectional view of still another example of a reinforcement film provided on the first major surface of the piezoelectric layer, the sidewall of the through-hole, and the second major surface of the piezoelectric layer.

As illustrated in FIG. 24, the reinforcement film 40 provided on the second major surface 12b of the piezoelectric layer 12 may be laid in both portions overlapping and not overlapping the air gap 13 as seen in the lamination direction of the support substrate 11 and the piezoelectric layer 12. This means that the reinforcement film 40 provided on the second major surface 12b of the piezoelectric layer 12 may be laid across the sidewall 13b of the air gap 13 as seen in the lamination direction of the support substrate 11 and the piezoelectric layer 12. In this case, the piezoelectric layer 12 is less deflected, and cracks are less likely to form in the piezoelectric layer 12.

For example, the reinforcement film 40 provided on the first major surface 12a of the piezoelectric layer 12 needs to be laid in a portion (a region within about 50 pm from the through-hole 19, for example), of the first major surface 12a of the piezoelectric layer 12, that is positioned around the through-hole 19. For example, the reinforcement film 40 provided on the second major surface 12b of the piezoelectric layer 12 needs to be laid in a portion (a region within about 50 pm from the through-hole 19, for example), of the second major surface 12b of the piezoelectric layer 12, that is positioned around the through-hole 19.

The following description illustrates modifications of the reinforcement film provided on the sidewall of the through-hole.

FIG. 25 is a schematic top view of an example of a reinforcement film provided on the sidewall of the through-hole so as to surround the through-hole. FIG. 26 is a schematic cross-sectional view of an example of a reinforcement film provided on the sidewall of the through-hole so as to surround the through-hole.

As illustrated in FIGS. 25 and 26, the reinforcement film 40 provided on the sidewall 19b of the through-hole 19 may surround the through-hole 19 as seen in the lamination direction of the support substrate 11 and the piezoelectric layer 12.

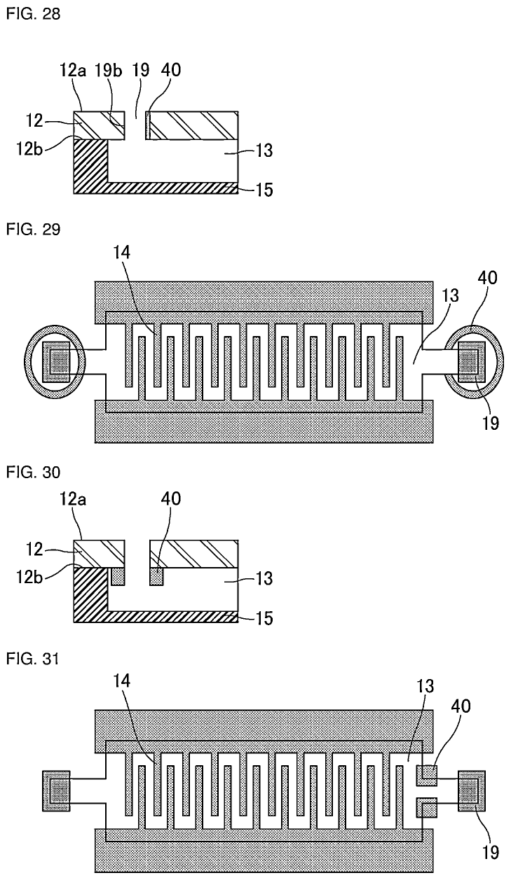

FIG. 27 is a schematic top view of an example of a reinforcement film provided only on a portion of the sidewall of the through-hole on the air gap side. FIG. 28 is a schematic cross-sectional view of an example of a reinforcement film provided only on a portion of the sidewall of the through-hole on the air gap side.

As illustrated in FIGS. 27 and 28, the reinforcement film 40 provided on the sidewall 19b of the through-hole 19 may be laid only on a portion of the sidewall 19b of the through-hole 19 on the air gap 13 side.

The following description illustrates modifications of the reinforcement film provided on the second major surface of the piezoelectric layer.

FIG. 29 is a schematic top view of an example of reinforcement films each provided on the second major surface of the piezoelectric layer so as to surround the through-hole. The left through-hole 19 indicates the case where the reinforcement film 40 surrounds the through-hole 19, and the right through-hole 19 indicates the case where the reinforcement film 40 surrounds the through-hole 19 except the air gap 13. FIG. 30 is a schematic cross-sectional view of an example of a reinforcement film provided on the second major surface of the piezoelectric layer so as to surround the through-hole.

As illustrated in FIGS. 29 and 30, the reinforcement film 40 provided on the second major surface 12b of the piezoelectric layer 12 surrounds the through-hole 19 as seen in the lamination direction of the support substrate 11 and the piezoelectric layer 12.

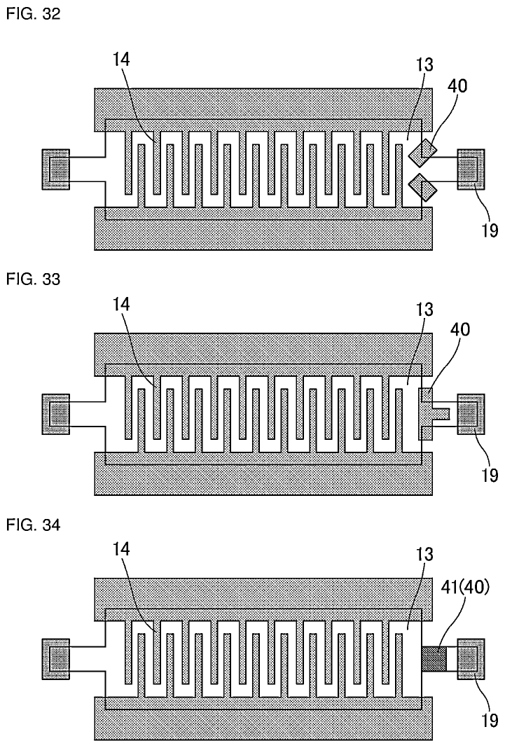

FIG. 31 is a schematic top view of a shape example of a reinforcement film provided on the second major surface of the piezoelectric layer near the right through-hole. FIG. 32 is a schematic top view of another shape example of the reinforcement film provided on the second major surface of the piezoelectric layer near the right through-hole. FIG. 33 is a schematic top view of still another shape example of the reinforcement film provided on the second major surface of the piezoelectric layer near the right through-hole.

As illustrated in FIG. 31, 32, or 33, when any reinforcement film 40 is provided on the second major surface 12b of the piezoelectric layer 12, the shape of the reinforcement film 40 seen in the lamination direction of the support substrate 11 and the piezoelectric layer 12 is not limited and can be a rectangular shape, a linear shape, a curved shape, a combination thereof, or the like, for example.

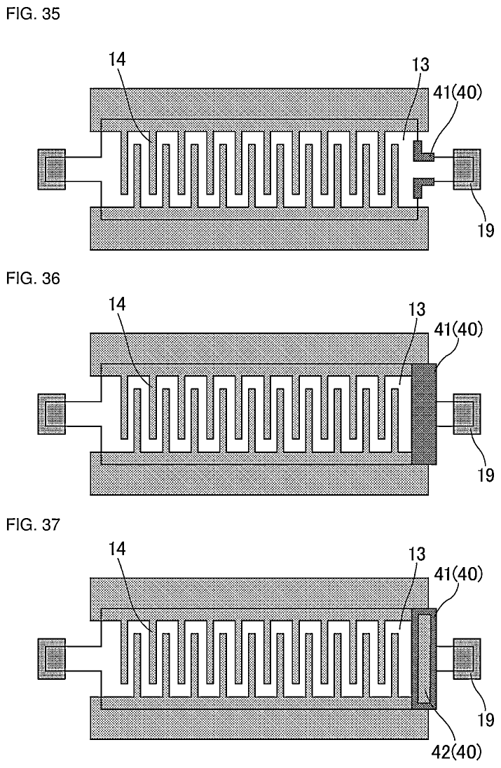

FIG. 34 is a schematic top view of an example of a reinforcement film that is provided near the right through-hole and includes a dielectric. FIG. 35 is a schematic top view of another example of a reinforcement film that is provided near the right through-hole and includes a dielectric. FIG. 36 is a schematic top view of still another example of a reinforcement film that is provided near the right through-hole and includes a dielectric.

As illustrated in FIG. 34, 35, or 36, the reinforcement film 40 may be a dielectric film 41. The material of the dielectric film 41 may be the same as that of the intermediate layer 15. The shape of the dielectric film 41 as seen in the lamination direction of the support substrate 11 and the piezoelectric layer 12 is not limited and can be a shape illustrated in FIG. 34, 35, or 36 or the like, for example.

FIG. 37 is a schematic top view of an example of a reinforcement film that is provided near the right through-hole and includes a reinforcement film including a dielectric and a reinforcement film including a metal.

As illustrated in FIG. 37, the reinforcement film 40 may include both the dielectric film 41 and a metal film 42. In this case, the positions, shapes, and the like of the dielectric film 41 and metal film 42 are not limited.

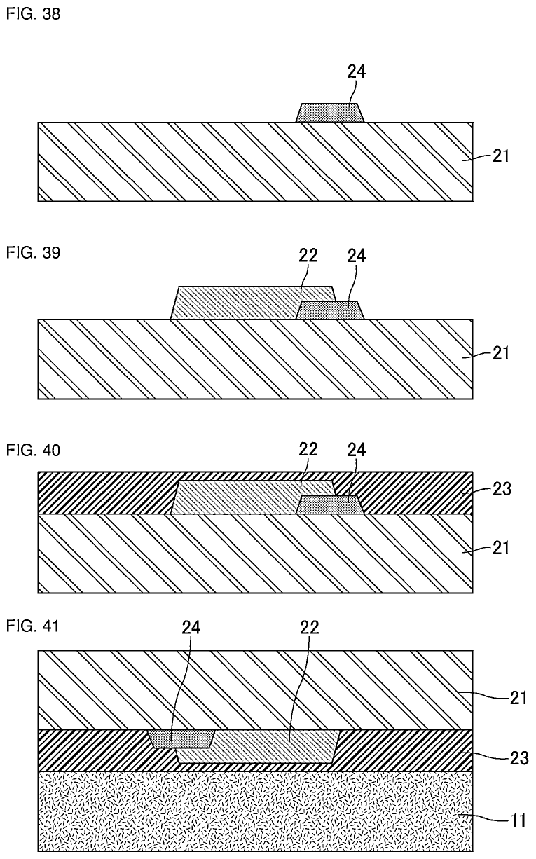

An example of a method of manufacturing the acoustic wave device according to the second preferred embodiment of the present invention will be described with reference to FIGS. 38 to The method of manufacturing the acoustic wave device 30, which is illustrated in FIGS. 38 to 45, is the same as the method of manufacturing the acoustic wave device 10, which is illustrated in FIGS. 11 to 17, except for performing a process to form a reinforcement layer 24 before forming the sacrificial layer 22 on the piezoelectric substrate 21 in order to form the reinforcement film 40 on the second major surface 12b of the piezoelectric layer 12. In order to form the reinforcement film 40 on the first major surface 12a of the piezoelectric layer 12 or the sidewall 19b of the through-hole 19, the reinforcement layer 24 just needs to be formed after the through-hole 19 is formed, for example.

FIG. 38 is a schematic cross-sectional view of an example of a process to form a reinforcement layer on a piezoelectric substrate.

As illustrated in FIG. 38, the reinforcement layer 24 is formed on the piezoelectric substrate 21. The reinforcement layer 24 is used to reinforce an etching hole.

The material of the reinforcement layer 24 is the same as that of the reinforcement film 40, for example. The reinforcement layer 24 is therefore a dielectric layer or a metal layer, for example. The reinforcement layer 24 can be formed by sputtering, for example.

FIG. 39 is a schematic cross-sectional view of an example of a process to form a sacrificial layer on the piezoelectric substrate.

As illustrated in FIG. 39, the sacrificial layer 22 is formed on the piezoelectric substrate 21 on which the reinforcement layer 24 is formed. The sacrificial layer 22 is formed so as to be laid over the reinforcement layer 24, for example.

FIG. 40 is a schematic cross-sectional view of an example of a process to form a joint layer.

As illustrated in FIG. 40, the joint layer 23 is formed so as to cover the sacrificial layer 22, and then the surface of the joint layer 23 is flattened.

FIG. 41 is a schematic cross-sectional view of an example of a process to bond a support substrate to the joint layer.

As illustrated in FIG. 41, the joint layer 23 is bonded to the support substrate 11.

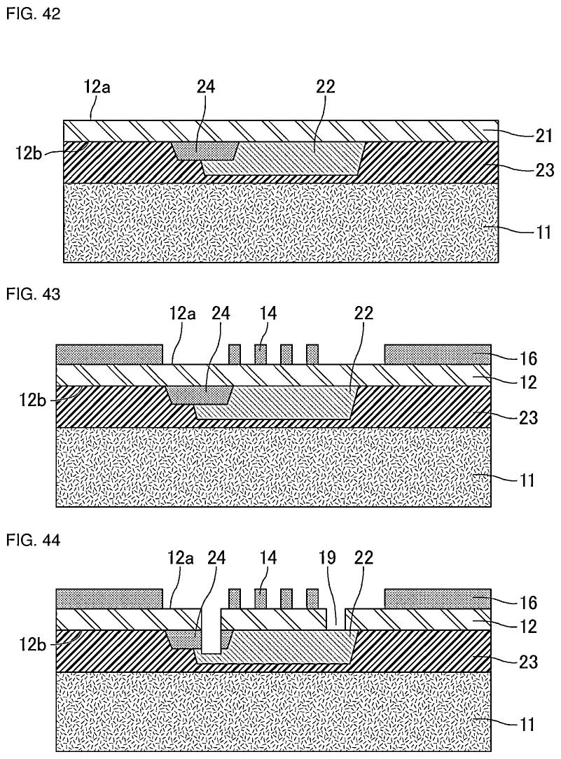

FIG. 42 is a schematic cross-sectional view of an example of a process to thin the piezoelectric substrate.

As illustrated in FIG. 42, the piezoelectric substrate 21 is thinned. The piezoelectric layer 12 is thus formed.

FIG. 43 is a schematic cross-sectional view of an example of a process to form functional electrodes and wiring electrodes.

As illustrated in FIG. 43, the functional electrodes 14 and the wiring electrodes 16 are formed on the first major surface 12a of the piezoelectric layer 12.

FIG. 44 is a schematic cross-sectional view of an example of a process to form through-holes.

As illustrated in FIG. 44, the through-holes 19 are formed in the piezoelectric layer 12. The through-holes 19 are formed so as to reach the sacrificial layer 22. The through-holes 19 are used as etching holes.

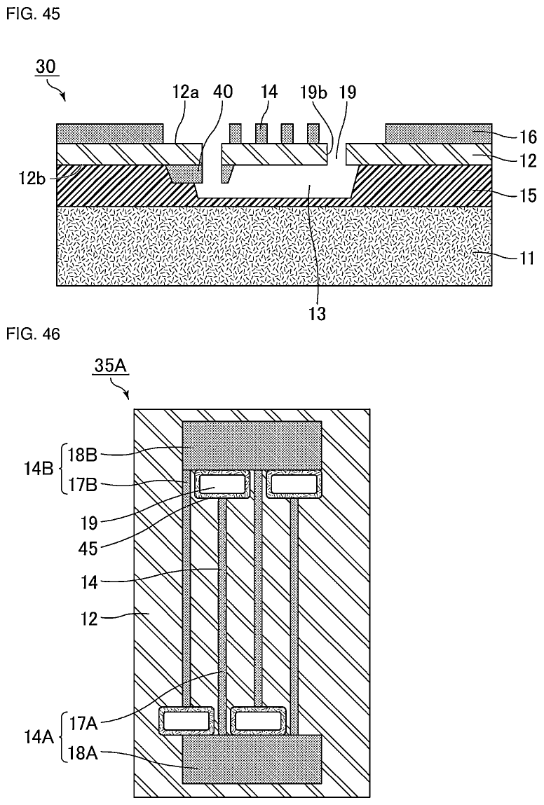

FIG. 45 is a schematic cross-sectional view of an example of a process to remove the sacrificial layer.

As illustrated in FIG. 45, the sacrificial layer 22 is removed by using the through-holes 19.

The acoustic wave device 30 is obtained as described above. In the acoustic wave device 30, the reinforcement film 40 derived from the reinforcement layer 24 is formed on the second major surface 12b of the piezoelectric layer 12.

### Third Preferred Embodiment

In an acoustic wave device according to a third preferred embodiment of the present invention, a through-hole is provided in at least one of a region between a first electrode and a second busbar electrode in the direction in which the first electrode extends and a region between a second electrode and a first busbar electrode in the direction in which the second electrode extends in at least one of a first major surface and a second major surface of a piezoelectric layer. On the side wall of the through-hole, a dielectric film is provided. The aforementioned configuration reduces spurious on the lower frequency side of the resonant frequency, so that the loss is reduced.

The following description illustrates examples as more specific disclosures of the acoustic wave device according to the third preferred embodiment of the present invention. The third preferred embodiment of the present invention is not necessarily limited to those examples.

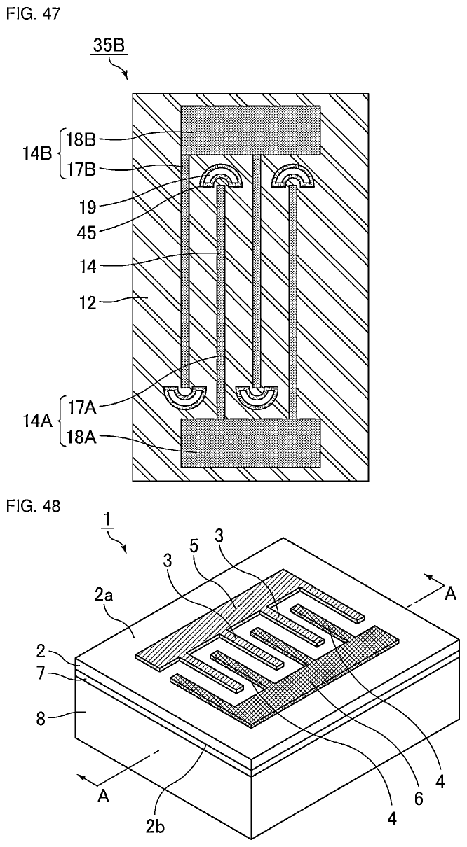

FIG. 46 is a schematic top view of an example of an acoustic wave device according to Example 3. FIG. 47 is a schematic top view of another example of the acoustic wave device according to Example 3.

In an acoustic wave device 35A according to Example 3 illustrated in FIG. 46, the through-hole 19 is provided in at least one of a region between the first electrode 17A and the second busbar electrode 18B in the direction in which the first electrode 17A extends and a region between the second electrode 17B and the first busbar electrode 18A in the direction in which the second electrode 17B extends, in at least one of the first major surface 12a and the second major surface 12b of the piezoelectric layer 12. On the side wall 19b of the through-hole 19, a dielectric film 45 is provided.

The material of the dielectric film 45 is SiO₂, SiN, Al₂O₃, Ta₂O₅, or the like, for example.

The dielectric film 45 may be provided on the entire sidewall 19b of the through-hole 19 or may be provided only on a portion of the sidewall 19b of the through-hole 19.

The reinforcement film 40 described in the second preferred embodiment may be the dielectric film 45. For example, the reinforcement film 40 illustrated in FIG. 21 or other drawings may be the dielectric film 45.

In the acoustic wave device 35A illustrated in FIG. 46, the through-hole 19 has a rectangular cross-section. However, the cross-sectional shape of the through-hole 19 is not limited and may be a circular shape, an elliptical shape, or the like, for example. The size of the cross-section of the through-hole 19 is not limited.

FIG. 47 is a schematic top view of another example of the acoustic wave device according to Example 3.

The through-hole 19 may include an arc-shaped cross-section like the acoustic wave device 35B illustrated in FIG. 47. In the example illustrated in FIG. 47, the arc of the through-hole 19 is disposed so as to face the first busbar electrode 18A or the second busbar electrode 18B.

Hereinafter, the thickness-shear mode and plate waves will be described in detail. The following description uses an example in which the functional electrode is an IDT electrode. A support in the following example corresponds to the support substrate in a preferred embodiment of the present invention, and an insulating layer corresponds to the intermediate layer.

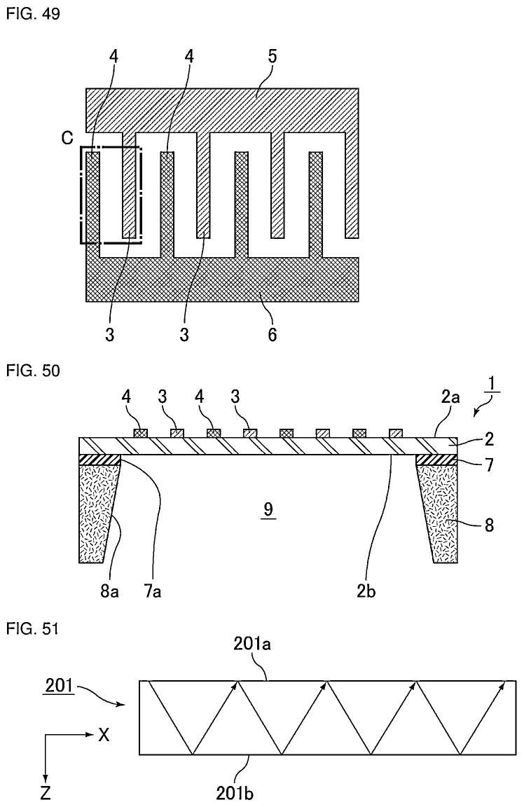

FIG. 48 is a schematic perspective view of the exterior of an example of an acoustic wave device using thickness-shear mode bulk waves. FIG. 49 is a plan view of an electrode structure on the piezoelectric layer of the acoustic wave device illustrated in FIG. 48. FIG. 50 is a cross-sectional view of a part along a line A-A in FIG. 48.

An acoustic wave device 1 includes a piezoelectric layer 2 composed of LiNbO₃, for example. The piezoelectric layer 2 may include LiTaO₃. As for the cut angle, the LiNbO₃ or LiTaO₃ is Z-cut, for example, but may be rotated Y-cut or X-cut. The propagation direction is preferably Y-propagation or X-propagation ±about 30°, for example. The thickness of the piezoelectric layer 2 is not limited but is preferably not less than about 50 nm and not greater than about 1000 nm, for example, for effective excitation of the thickness-shear mode. The piezoelectric layer 2 includes a first major surface 2a and a second major surface 2b, which face each other. On the first major surface 2a of the piezoelectric layer 2, an electrode 3 and an electrode 4 are provided. Herein, the electrode 3 is an example of the “first electrode”, and the electrode 4 is an example of the “second electrode”. In FIGS. 48 and 49, plural electrodes 3 are plural first electrode fingers coupled to a first busbar electrode 5, and plural electrodes 4 are plural second electrode fingers coupled to a second busbar electrode 6. The plural electrodes 3 are interdigitated with the plural electrodes 4. Each of the electrodes 3 and 4 has a rectangular shape and has a length direction. Each electrode 3 faces the electrodes 4 adjacent thereto in a direction orthogonal to the length direction. These plural electrodes 3 and 4, first busbar electrode 5, and second busbar electrode 6 define an interdigital transducer (IDT) electrode. Both the length direction of the electrodes 3 and 4 and the direction orthogonal to the length direction of the electrodes 3 and 4 intersect the thickness direction of the piezoelectric layer 2. That is, each electrode 3 faces the electrodes 4 adjacent thereto in a direction that intersects the thickness direction of the piezoelectric layer 2. The length direction of the electrodes 3 and 4 may be replaced with a direction orthogonal to the length direction of the electrodes 3 and 4 illustrated in FIGS. 48 and 49. Specifically, in FIGS. 48 and 49, the electrodes 3 and 4 may extend in the direction in which the first busbar electrode 5 and second busbar electrode 6 extend. In this case, the first busbar electrode 5 and the second busbar electrode 6 extend in the direction in which the electrodes 3 and 4 extend in FIGS. 48 and 49. Plural structure pairs each including adjacent electrodes 3 and 4 that are respectively coupled to one potential and the other potential are provided in the direction orthogonal to the length direction of the electrodes 3 and 4. Herein, the adjacent electrodes 3 and 4 refer to electrodes 3 and 4 that are disposed with a space therebetween but do not refer to electrodes 3 and 4 that are disposed in direct contact with each other. When the electrodes 3 and 4 are adjacent to each other, no electrode that is coupled to a hot or ground electrode, including the other electrodes 3 and 4, is disposed between the electrodes 3 and 4. The number of pairs of electrodes 3 and 4 is not necessarily a whole number and may be 1.5, 2.5, or the like. The center-to-center distance, that is, the pitch between electrodes 3 and 4 is preferably not less than about 1 μm and not greater than about 10 μm, for example. The center-to-center distance between electrodes 3 and 4 refers to the distance between the center of the width dimension of the electrode 3 in the direction orthogonal to the length direction of the electrode 3 and the center of the width dimension of the electrode 4 in the direction orthogonal to the length direction of the electrode 4. Furthermore, at least one of the electrode 3 and the electrode 4 includes plural electrodes (when the number of pairs of electrodes is 1.5 or more, each pair of electrodes including electrodes 3 and 4), the center-to-center distance between electrodes 3 and 4 refers to the average center-to-center distance between adjacent electrodes 3 and 4 among 1.5 or more pairs of electrodes 3 and 4. The width of the electrodes 3 and 4, that is, the dimension of the electrodes 3 and 4 in the direction in which the electrodes 3 and 4 face each other is preferably not less than about 150 nm and not greater than about 1000 nm, for example.

In the third preferred embodiment, when the piezoelectric layer is Z-cut, the direction orthogonal to the length direction of the electrodes 3 and 4 is the direction orthogonal to the polarization direction of the piezoelectric layer 2, except when the piezoelectric layer 2 includes a piezoelectric with another cut angle. Herein, “being orthogonal” is not limited to only “being strictly orthogonal” and may include “being substantially orthogonal (the angle between the direction orthogonal to the length direction of the electrodes 3 and 4 and the polarization direction may be about 90°±10°, for example)”.

On the second major surface 2b side of the piezoelectric layer 2, a support 8 is laminated with an insulating layer 7 interposed therebetween. The insulating layer 7 and the support 8 are frame-shaped and include cavities 7a and 8a as illustrated in FIG. 50, which form an air gap 9. The air gap 9 is provided not to impede vibration in an excitation region C (see FIG. 49) of the piezoelectric layer 2. The aforementioned support 8 is laminated on the second major surface 2b with the insulating layer 7 interposed therebetween in such a position as not to overlap a portion where at least one pair of electrodes 3 and 4 is provided. The insulating layer 7 is not necessarily provided. The support 8 can therefore be laid directly or indirectly on the second major surface 2b of the piezoelectric layer 2.

The insulating layer 7 includes silicon oxide, for example. In addition to silicon oxide, the insulating layer 7 can be composed of a proper insulating material, such as silicon oxynitride or alumina. The support 8 includes Si. The orientation of the face of Si on the piezoelectric layer 2 side may be (100), (110), or (111). Preferably, the support 8 includes high-resistance Si with a resistivity of not less than about 4 kQ. The support 8 can be composed of a proper insulating material or a proper semiconductor material. Examples of the material of the support 8 can include piezoelectrics, such as aluminum oxide, lithium tantalate, lithium niobate, and crystal, various ceramics, such as alumina, magnesia, sapphire, silicon nitride, aluminum nitride, silicon carbide, zirconia, cordierite, mullite, steatite, and forsterite, dielectrics, such as diamond and glass, and semiconductors, such as gallium nitride.

The plural electrodes 3 and 4, the first busbar electrode 5, and the second busbar electrode 6 include a proper metal or alloy, such as Al or AlCu alloy. In the third preferred embodiment, the plural electrodes 3 and 4, the first busbar electrode 5, and the second busbar electrode 6 include a structure in which an Al film is laminated on a Ti film. The plural electrodes 3 and 4, the first busbar electrode 5, and the second busbar electrode 6 may include an adhesion layer other than the Ti film.

To drive the acoustic wave device 1, alternating-current voltage is applied across the plural electrodes 3 and the plural electrodes 4. To be more specific, alternating-current voltage is applied across the first busbar electrode 5 and the second busbar electrode 6. This can provide resonance characteristics using thickness-shear mode bulk waves excited in the piezoelectric layer 2. In the acoustic wave device 1, furthermore, d/p is not greater than about 0.5, for example, where d is the thickness of the piezoelectric layer 2 and p is the center-to-center distance between any adjacent electrodes 3 and 4 among the plural pairs of electrodes 3 and 4. The thickness-shear mode bulk waves can therefore be excited effectively, thus providing good resonance characteristics. More preferably, d/p is not greater than about for example. In this case, it is possible to provide much better resonance characteristics. When at least one of the electrode 3 and the electrode 4 includes plural electrodes as the third preferred embodiment, that is, when the acoustic wave device 1 includes 1.5 or more pairs of electrodes, each pair including any electrodes 3 and 4, the center-to-center distance p between adjacent electrodes 3 and 4 refers to the average center-to-center distance of each pair of adjacent electrodes 3 and 4.

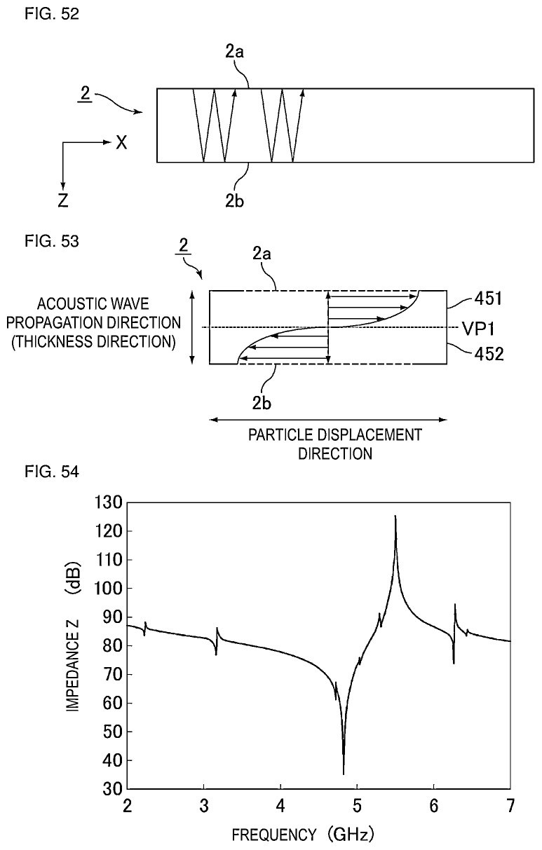

In the acoustic wave device 1 of the third preferred embodiment, due to the aforementioned configuration, the Q value is less likely to decrease even when the number of pairs of electrodes 3 and 4 is reduced for size reduction. This is because the aforementioned configuration defines a resonator not requiring reflectors on both sides and the propagation loss is small. The reflectors are not required because the acoustic wave device 1 uses thickness-shear mode bulk waves. The difference between Lamb waves used in an acoustic wave device in the related art and the aforementioned thickness-shear mode bulk waves will be described with reference to FIGS. 51 and 52.

FIG. 51 is a schematic elevational cross-sectional view for explaining Lamb waves propagating in a piezoelectric film of an acoustic wave device. As illustrated in FIG. 51, in an acoustic wave device described in Japanese Unexamined Patent Application Publication No. 2012-257019, waves propagate in a piezoelectric film 201 as indicated by arrows. Herein, in the piezoelectric film 201, a first major surface 201a and a second major surface 201b face each other, and the thickness direction connecting the first major surface 201a to the second major surface 201b is a Z direction. An X direction is the direction in which the electrode fingers of the IDT electrode are arranged. As illustrated in FIG. 51, Lamb waves propagate in the X direction. Since Lamb waves are plate waves, the entire piezoelectric film 201 vibrates, but the waves propagate in the X direction. The resonance characteristics are therefore obtained by disposing reflectors on both sides. This causes a wave propagation loss. When a size is reduced, that is, when the number of pairs of electrode fingers is reduced, therefore, the Q value decreases.

FIG. 52 is a schematic elevational cross-sectional view for explaining thickness-shear mode bulk waves propagating in the piezoelectric layer of an acoustic wave device. As illustrated in FIG. 52, in the acoustic wave device 1 of the third preferred embodiment, the displacement of vibration is in the thickness-shear direction, and most waves propagate in the direction connecting the first major surface 2a of the piezoelectric layer 2 to the second major surface 2b, that is, in the Z direction to resonate. The component of the waves in the X direction is significantly smaller than the component in the Z direction. This wave propagation in the Z direction provides resonance characteristics, and no reflectors are necessary. The propagation loss due to propagation to reflectors is therefore not produced. The Q value is therefore less likely to decrease even when the number of pairs of electrodes including electrodes 3 and 4 is reduced for size reduction.

FIG. 53 is a diagram illustrating the amplitude direction of thickness-shear mode bulk waves. As illustrated in FIG. 53, the amplitude direction of thickness-shear mode bulk waves in a first region 451 included in the excitation region C of the piezoelectric layer 2 is opposite to that in a second region 452 included in the excitation region C. FIG. 53 schematically illustrates bulk waves when voltage is applied across the electrode 3 and the electrode 4 so that the potential of the electrode 4 is higher than that of the electrode 3. The first region 451 is a region between a virtual plane VP1 and the first major surface 2a in the excitation region C. The virtual plane VP1 is orthogonal to the thickness direction of the piezoelectric layer 2 and divides the piezoelectric layer 2 into two. The second region 452 is a region between the virtual plane VP1 and the second major surface 2b in the excitation region C.

As described above, in the acoustic wave device 1, at least a pair of electrodes including electrodes 3 and 4 is disposed, but the waves do not propagate in the X direction. The number of pairs of electrodes including electrodes 3 and 4 therefore does not need to be greater than 1. That is, the acoustic wave device 1 only needs to include at least one pair of electrodes.

For example, the aforementioned electrode 3 is an electrode coupled to the hot potential while the electrode 4 is an electrode coupled to the ground potential. However, the electrode 3 may be coupled to the ground potential while the electrode 4 is coupled to the hot potential. In the third preferred embodiment, at least one pair of electrodes include an electrode coupled to the hot potential and an electrode coupled to the ground potential as described above, and no floating electrode is provided.

FIG. 54 is a diagram illustrating an example of resonance characteristics of the acoustic wave device illustrated in FIG. 48. The design parameters of an example of the acoustic wave device 1 including the resonance characteristics are as follows.

Piezoelectric layer 2: LiNbO₃ with Euler angles (0°, 0°, 90°), the thickness=about 400 nm

The length of the region where the electrodes 3 and 4 overlap each other as seen in the direction orthogonal to the length direction of the electrodes 3 and 4, that is, the length of the excitation region C=about 40 μm, the number of pairs of electrodes including the electrodes 3 and 4=21, the center-to-center distance between electrodes=about 3 μm, the width of the electrodes 3 and 4=about 500 nm, and d/p=about 0.133

Insulating layer 7: about 1 μm-thick silicon oxide film

Support 8: Si substrate

The length of the excitation region C is the dimension of the excitation region C along the length direction of the electrodes 3 and 4.

In the acoustic wave device 1, the electrode-to-electrode distance in each pair of electrodes including electrodes 3 and 4 is equal among all the plural pairs of electrodes. That is, the electrodes 3 and the electrodes 4 are disposed at equal pitches.

As can be seen in FIG. 54, the acoustic wave device 1 has good resonance characteristics with a fractional bandwidth of about 12.5%, for example, although the acoustic wave device 1 does not include reflectors.

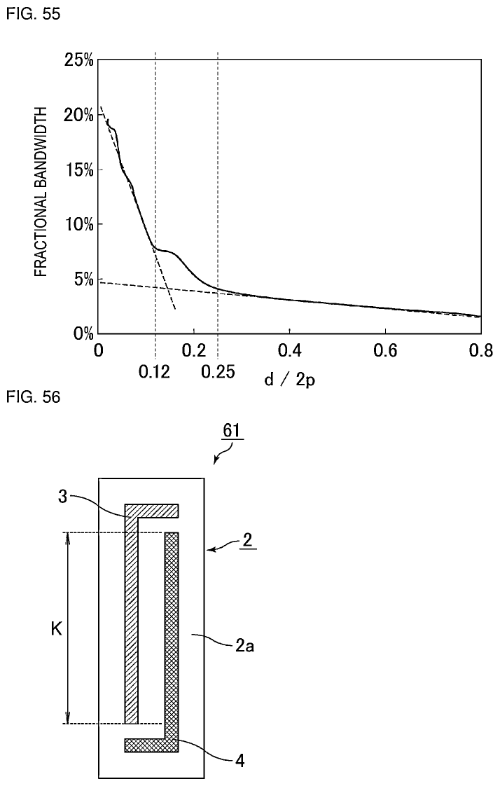

As described above, d/p is preferably not greater than about 0.5 and more preferably not greater than about 0.24, for example, in the third preferred embodiment where d is the thickness of the piezoelectric layer 2 and p is the center-to-center distance between electrodes 3 and 4. This will be described with reference to FIG. 55.

Plural acoustic wave devices were obtained in a similar manner to the acoustic wave device that has resonance characteristics and is illustrated in FIG. 54 while d/2p was varied. FIG. 55 is a diagram illustrating the relationship between d/2p and the fractional bandwidth as a resonator, of each acoustic wave device where p is the center-to-center distance between adjacent electrodes and d is the thickness of the piezoelectric layer.

As can be seen in FIG. 55, when d/2p is greater than about 0.25, that is, when d/p>about 0.5, the fractional bandwidth is less than about 5% even when d/p is adjusted, for example. In contrast, when d/2p about 0.25, that is, when d/p about 0.5, the fractional bandwidth can be about 5% or higher by changing d/p within that range, for example. It is thus possible to provide a resonator having a high coupling coefficient. When d/2p is not greater than about 0.12, that is, when d/p is not greater than about 0.24, the fractional bandwidth can be increased to about 7% or higher, for example. In addition, when d/p is adjusted within this range, it is possible to provide a resonator with a wider fractional bandwidth. It is therefore possible to implement a resonator having a higher coupling coefficient. This reveals that when d/p is set not greater than about 0.5, for example, the resonator that uses thickness-shear mode bulk waves and has a high coupling coefficient can be implemented.

As described above, the at least one pair of electrodes may include one pair of electrodes, and when the at least one pair of electrodes include one pair of electrodes, p described above is the center-to-center distance between the adjacent electrodes 3 and 4. When the at least one pair of electrodes includes 1.5 or more pairs or electrodes, p is the average center-to-center distance between adjacent electrodes 3 and 4.

When the piezoelectric layer 2 has variations in thickness, the thickness d of the piezoelectric layer can be an average thickness of the piezoelectric layer 2.

FIG. 56 is a plan view of another example of the acoustic wave device using thickness-shear mode bulk waves.

In an acoustic wave device 61, a pair of electrodes including an electrode 3 and an electrode 4 is provided on the first major surface 2a of the piezoelectric layer 2. K in FIG. 56 indicates an intersecting width. As described above, in the acoustic wave device of the third preferred embodiment, the number of pairs of electrodes may be one. Even in such a case, thickness-shear mode bulk waves can be effectively excited when d/p described above is not greater than about 0.5, for example.

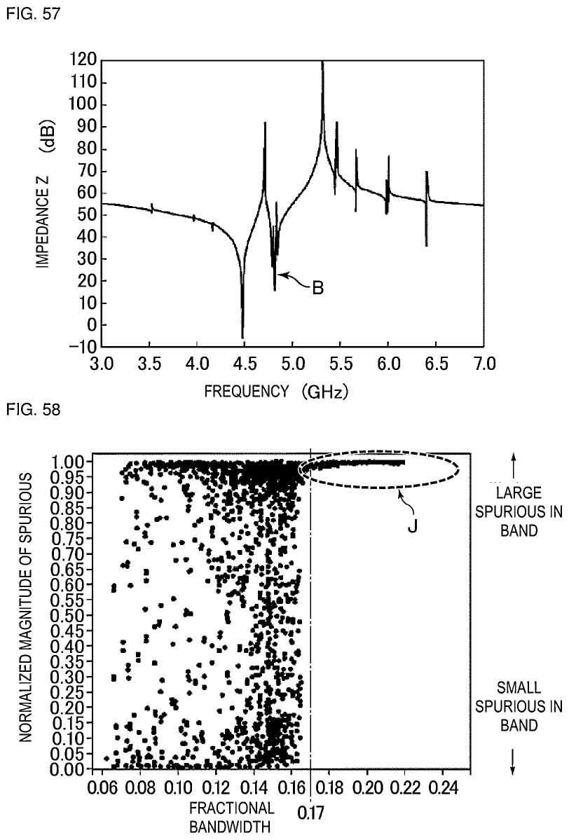

In the acoustic wave device of the third preferred embodiment, preferably, a metallization ratio MR satisfies: MR about 1.75(d/p)+0.075, for example, where the metallization ratio MR is a metallization ratio of any adjacent electrodes 3 and 4 among the plural electrodes 3 and 4 to the excitation region, which is the region where the adjacent electrodes 3 and 4 overlap each other as seen in the direction in which the electrodes 3 and 4 face each other. In this case, spurious can be effectively reduced. This will be described with reference to FIGS. 57 and 58.

FIG. 57 is a referential diagram illustrating an example of resonance characteristics of the acoustic wave device illustrated in FIG. 48. Spurious indicated by an arrow B appears between the resonant frequency and the anti-resonant frequency. Herein, d/p was set to about 0.08, and Euler angles of LiNbO3 was set to (0°, 0°, 90°), for example. The above-described metallization ratio MR was set to about 0.35, for example.

The metallization ratio MR will be described with reference to FIG. 49. Focusing on a pair of electrodes 3 and 4 in the electrode structure of FIG. 49, it is assumed that only this pair of electrodes 3 and 4 is provided. In this case, the part surrounded by the dashed-dotted line C is the excitation region. This excitation region includes a region of the electrode 3 overlapping the electrode 4 as the electrodes 3 and 4 are seen in the direction orthogonal to the length direction of the electrodes 3 and 4, that is, in the direction in which the electrodes 3 and 4 face each other, a region of the electrode 4 overlapping the electrode 3, and a region where the electrodes 3 and 4 overlap each other in the region between the electrode 3 and the electrode 4. The metallization ratio MR is the area of the electrodes 3 and 4 in the excitation region C with respect to the area of the excitation region. That is, the metallization ratio MR is the ratio of the area of the metallized portion to the area of the excitation region.

When the electrode structure includes plural pairs of electrodes, MR can be a ratio of metallized part included in all of the excitation regions to the total area of the excitation regions.

FIG. 58 is a diagram illustrating the relationship between the fractional bandwidth and the amount of phase rotation of the impedance of spurious. The amount of phase rotation is regarded as the magnitude of the spurious and is normalized by 180 degrees. The relationship was obtained for many acoustic wave resonators formed according to the third preferred embodiment. The fractional bandwidth was adjusted by variously changing the film thickness of the piezoelectric layer and the dimensions of the electrodes. FIG. 58 is the result when the piezoelectric layer was composed of Z-cut LiNbO₃. However, the results for piezoelectric layers having another cut angle show the same tendency.

In the region surrounded by an ellipse J in FIG. 58, the magnitude of spurious is as large as about 1.0, for example. As can be seen in FIG. 58, when the fractional bandwidth is greater than about 0.17, that is, greater than about 17%, for example, large spurious with a spurious level of not less than 1 appears in the pass band even if the parameters constituting the fractional bandwidth are changed. Like the resonance characteristics illustrated in FIG. 57, large spurious indicated by the arrow B appears. Preferably, the fractional bandwidth is therefore not greater than about 17%, for example. In this case, spurious can be reduced by adjusting the film thickness of the piezoelectric layer 2, dimensions of the electrodes 3 and 4, and the like.

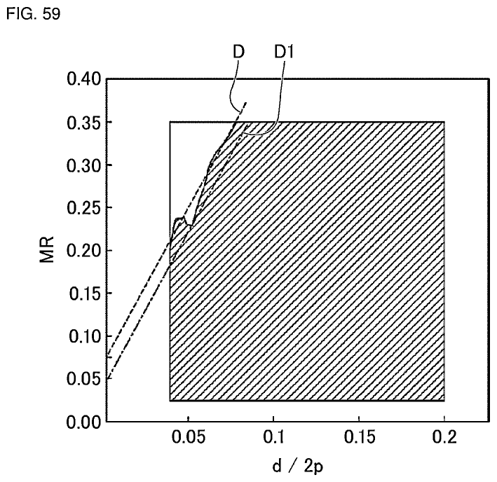

FIG. 59 is a diagram illustrating the relationship between d/2p, the metallization ratio MR, and the fractional bandwidth. Various acoustic wave devices having different values of d/2p and MR were formed according to the aforementioned acoustic wave device, and the fractional bandwidth thereof was measured.

The hatched portion to the right of a dashed line D in FIG. 59 is a region in which the fractional bandwidth is not greater than about 17%, for example. The boundary between the region with hatching and the region without hatching is represented by MR=about 3.5(d/2p)+0.075, that is, MR=1.75(d/p)+0.075, for example. Preferably, therefore, MR≤about 1.75(d/p)+0.075, for example. In this case, the fractional bandwidth can be easily set not greater than about 17%, for example. The region to the right of MR=about 3.5(d/2p)+0.05, for example, indicated by a dotted-dashed line D1 in FIG. 59 is more preferred. That is, when MR≤about 1.75(d/p)+0.05, the fractional bandwidth can surely be set not greater than about 17%, for example.

FIG. 60 is a diagram illustrating a fractional bandwidth map with respect to Euler angles (0°, θ, ψ) of LiNbO₃ as d/p is reduced infinitesimally close to zero.

Hatched portions in FIG. 60 are regions where the fractional bandwidth is at least not less than about 5%, for example. The ranges of the regions are approximated into the ranges expressed by Expressions (1), (2), and (3) below.

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)

(0°±10°, [180°−30° (1−(ψ−90)²/8100)^{1/2}] to 180°, any ψ) Expression (3)

It is therefore preferable that the Euler angles are within the range expressed by Expression (1), (2), or (3) so that the fractional bandwidth can be widened sufficiently.

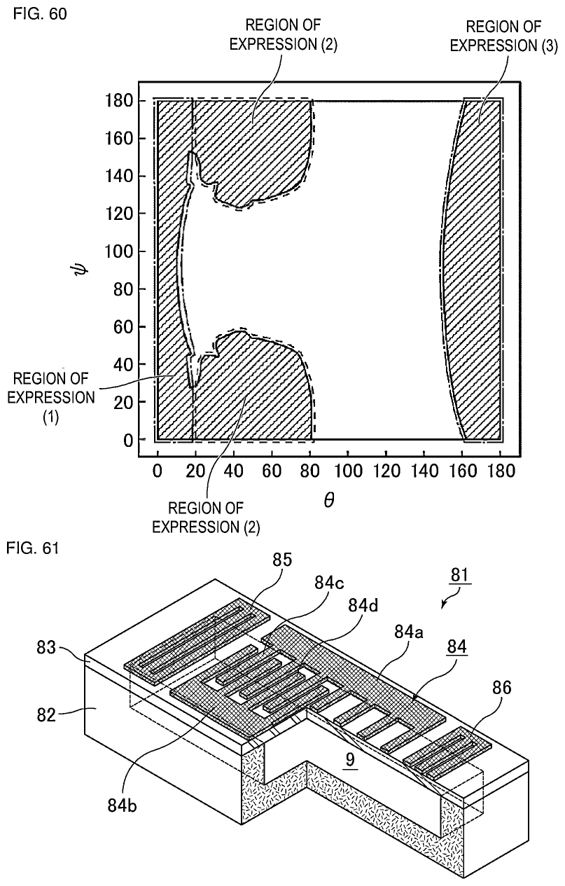

FIG. 61 is a partially-cutaway perspective view for explaining an example of an acoustic wave device using Lamb waves.

An acoustic wave device 81 includes a support substrate 82. The support substrate 82 is provided with a recess opened in the top surface. On the support substrate 82, a piezoelectric layer 83 is laminated. The air gap 9 is thus provided. Above the air gap 9, an IDT electrode 84 is provided on the piezoelectric layer 83. On both sides of the IDT electrode 84 in the acoustic wave propagation direction, reflectors 85 and 86 are provided. In FIG. 61, a dashed line indicates the outer edge of the air gap 9. The IDT electrode 84 includes a first busbar electrode 84a, a second busbar electrode 84b, plural electrodes 84c as first electrode fingers, and plural electrodes 84d as second electrode fingers. The plural electrodes 84c are coupled to the first busbar electrode 84a. The plural electrodes 84d are coupled to the second busbar electrode 84b. The plural electrodes 84c are interdigitated with the plural electrodes 84d.

In the acoustic wave device 81, when an alternating-current electric field is applied to the IDT electrode 84 above the air gap 9, Lamb waves as plate waves are excited. Since the reflectors 85 and 86 are provided on the both sides, the acoustic wave device 81 is able to have resonance characteristics by the Lamb waves.

As described above, an acoustic wave device according to a preferred embodiment of the present invention may use plate waves, such as Lamb waves.

Acoustic wave devices according to various preferred embodiments of the present invention may use bulk waves. An acoustic wave device according to a preferred embodiment of the present invention is applicable to bulk acoustic wave (BAW) elements. In this case, the functional electrode includes an upper electrode and a lower electrode.

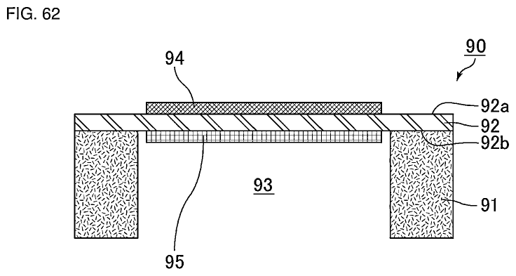

FIG. 62 is a schematic cross-sectional view of an example of an acoustic wave device using bulk waves.

An acoustic wave device 90 includes a support substrate 91. An air gap 93 is provided so as to penetrate the support substrate 91. On the support substrate 91, a piezoelectric layer 92 is laminated. On a first major surface 92a of the piezoelectric layer 92, an upper electrode 94 is provided. On a second major surface 92b of the piezoelectric layer 92, a lower electrode 95 is provided.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric layer including a first major surface and a second major surface that face each other;
a functional electrode provided on at least one of the first major surface and the second major surface of the piezoelectric layer; and
a support substrate laminated on a second major surface side of the piezoelectric layer; wherein
an air gap is provided between the support substrate and the piezoelectric layer;
at least a portion of the functional electrode overlaps the air gap as seen in a lamination direction of the support substrate and the piezoelectric layer;
a through-hole that penetrates the piezoelectric layer and reaches the air gap is provided; and
a protrusion is provided in a region defining an outer edge of the through-hole in the first major surface of the piezoelectric layer and is more protruded than a region where the through-hole is not provided.

2. The acoustic wave device according to claim 1, wherein at least a portion of the protrusion includes a curved surface.

3. The acoustic wave device according to claim 1, wherein at least one of an outer wall and an inner wall of the protrusion includes a curved surface.

4. The acoustic wave device according to claim 1, wherein an outer wall of the protrusion has a shape widening from inside toward outside or a shape narrowing from inside toward outside.

5. The acoustic wave device according to claim 1, wherein at least a portion of the through-hole is curved as seen in the lamination direction of the support substrate and the piezoelectric layer.

6. The acoustic wave device according to claim 1, wherein an end portion of the through-hole on a first major surface side of the piezoelectric layer has an inverse tapered shape increasing in cross-sectional area toward the first major surface.

7. The acoustic wave device according to claim 1, further comprising:
an intermediate layer provided between the support substrate and the piezoelectric layer; wherein
the air gap is provided in a portion of the intermediate layer.

8. The acoustic wave device according to claim 1, wherein the protrusion includes a reinforcement film provided on the first major surface of the piezoelectric layer.

9. The acoustic wave device according to claim 8, wherein the reinforcement film is further provided on a sidewall of the through-hole.

10. The acoustic wave device according to claim 8, wherein the reinforcement film is further provided on the second major surface of the piezoelectric layer.

11. The acoustic wave device according to claim 10, wherein the air gap is adjacent to a surface of the reinforcement film provided on the second major surface of the piezoelectric layer.

12. The acoustic wave device according to claim 10, wherein the reinforcement film provided on the second major surface of the piezoelectric layer is in contact with a sidewall of the air gap.

13. The acoustic wave device according to claim 10, wherein the reinforcement film provided on the second major surface of the piezoelectric layer extends across a sidewall of the air gap as seen in the lamination direction of the support substrate and the piezoelectric layer.

14. The acoustic wave device according to claim 8, wherein a material of the reinforcement film is a dielectric. The acoustic wave device according to claim 8, wherein a material of the reinforcement film is any one of SiO₂, SiN, and Al₂O₃.

16. The acoustic wave device according to claim 8, wherein a material of the reinforcement film is a metal.

17. The acoustic wave device according to claim 1, wherein
the functional electrode includes one or more first electrodes, a first busbar electrode coupled to the one or more first electrodes, one or more second electrodes, and a second busbar electrode coupled to the one or more second electrodes;
the through-hole is provided in at least one of a region between the first electrode and the second busbar electrode in a direction in which the first electrode extends and a region between the second electrode and the first busbar electrode in a direction in which the second electrode extends, in at least one of the first major surface and the second major surface of the piezoelectric layer; and
a dielectric film is provided on a side wall of the through-hole.

18. The acoustic wave device according to claim 1, wherein
the functional electrode includes one or more first electrodes, a first busbar electrode coupled to the one or more first electrodes, one or more second electrodes, and a second busbar electrode coupled to the one or more second electrodes; and
the one or more first electrodes, the first busbar electrode, the one or more second electrodes, and the second busbar electrode are provided on the first major surface of the piezoelectric layer.

19. The acoustic wave device according to claim 17, wherein a thickness of the piezoelectric layer is not greater than 2p where p is a center-to-center distance between a first electrode and a second electrode that are adjacent among the one or more first electrodes and the one or more second electrodes.

20. The acoustic wave device according to claim 1, wherein the piezoelectric layer includes lithium niobate or lithium tantalate.

21. The acoustic wave device according to claim 20, wherein the acoustic wave device is structured to generate a thickness-shear mode bulk wave.

22. The acoustic wave device according to claim 17, wherein d/p about 0.5 where d is a thickness of the piezoelectric layer and p is a center-to-center distance between a first electrode and a second electrode that are adjacent among the one or more first electrodes and the one or more second electrodes.

23. The acoustic wave device according to claim 22, wherein d/p≤about 0.24.

24. The acoustic wave device according to claim 17, wherein MR≤about 1.75(d/p)+0.075, where MR is a metallization ratio that is a ratio of an area of a first electrode and a second electrode that are adjacent among the one or more first electrodes and the one or more second electrodes to an area of an excitation region where the first electrode and the second electrode that are adjacent overlap each other as seen in a direction in which the first electrode and the second electrode that are adjacent face each other, d is a thickness of the piezoelectric layer, and p is a center-to-center distance between the first electrode and the second electrode that are adjacent.

25. The acoustic wave device according to claim 24, wherein MR≤about 1.75(d/p)+0.05.

26. The acoustic wave device according to claim 1, wherein the functional electrode includes an upper electrode provided on the first major surface of the piezoelectric layer and a lower electrode provided on the second major surface of the piezoelectric layer.

27. The acoustic wave device according to claim 20, wherein
Euler angles (φ, θ, ψ) of the lithium niobate or the lithium tantalate are within a range expressed by Expression (1), (2), or (3):
(0°±10°, 0° to 20°, any ψ) Expression (1)
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)
(0°±10°, [180°−30° (1−(ψ−90)²/8100)^{1/2}] to 180°, any ψ) Expression (3).
